(19) United States
(12) Patent Application Publication
(10) Pub. No.: US 2024/0213395 A1
(43) Pub. Date: Jun. 27, 2024

(54) LIGHT SENSING ELEMENT AND MANUFACTURING METHOD THEREOF

(71) Applicant: Taiwan-Asia Semiconductor Corporation, Hsinchu City (TW)

(72) Inventors: Yang-Ting LIU, Hsinchu City (TW); Keng-Ying LIAO, Hsinchu City (TW); You-Hsien CHANG, Hsinchu City (TW)

(21) Appl. No.: 18/396,161

(22) Filed: Dec. 26, 2023

(30) Foreign Application Priority Data
Dec. 27, 2022 (TW) 111150240

(51) Int. Cl. H01L 31/18; H01L 31/0216

(52) U.S. Cl. CPC H01L 31/1844; H01L 31/02162

(57) ABSTRACT

The present invention provides a manufacturing method of a light sensing element. The method includes the following steps: providing a preformed structure, wherein the preformed structure includes a semiconductor structure and a bandpass filter layer stacked on the semiconductor structure; performing a laser cutting process on the preformed structure along a direction perpendicular to a surface of the bandpass filter layer so that the preformed structure is cut into a plurality of light sensing elements. Each light sensing element has a plurality of sidewalls. Each sidewall forms a scorched surface by the laser cutting process to block the entry of external light.

### CROSS-REFERENCES TO RELATED APPLICATIONS

This application claims priority to Taiwan Patent Application No. 111150240 filed on Dec. 27, 2022, which is hereby incorporated by reference in its entirety.

### BACKGROUND OF THE INVENTION

### Field of the Invention

The present invention relates to a light sensing element and a manufacturing method thereof, in particular to a light sensing element and a manufacturing method thereof that can effectively reduce noise.

### Descriptions of the Related Art

Conventional light sensing elements will limit the passage of light within a specific spectrum by arranging a bandpass filter (BPF) film layer on the light receiving surface to provide the sensing function of specific light. At the same time, the bandpass filter film layer reflects light outside the specific spectrum to limit its entry into the light absorbing layer of the light sensing element, thereby reducing unnecessary noise generation.

It is known that in conventional process, a cutting operation is performed on the preformed light sensing structure before the light sensing elements are formed to obtain the light sensing elements of the required size. However, most of the current cutting operations use diamond knives to cut so that the sidewalls of the light sensing elements formed by cutting become a light-transmissive surface. Since there is no BPF film layer on these sidewall surfaces, once light enters the interior of the device from any sidewall surface, light outside the specific spectrum will be absorbed by the light absorbing layer, resulting in noise generation. As a result, the sensing accuracy and/or performance of conventional light sensing elements will be affected.

Therefore, it is worthwhile to study how to design a light sensing element and a manufacturing method thereof that can solve the above problems and suppress the noise generation.

### SUMMARY OF THE INVENTION

The objective of the present invention is to provide a manufacturing method for a light sensing element that can effectively reduce noise.

Another objective of the present invention is to provide a light sensing element manufactured using the aforementioned manufacturing method.

In order to achieve the above objectives, a manufacturing method of a light sensing element of the present invention includes the following steps: providing a preformed structure, wherein the preformed structure includes a semiconductor structure and a bandpass filter layer stacked on the semiconductor structure; and performing at least one laser cutting process on the preformed structure in a direction perpendicular to a surface of the bandpass filter layer to cut the preformed structure into a plurality of light sensing elements, each of the light sensing elements having a plurality of sidewalls; wherein each of the sidewalls forms a scorched surface by the at least one laser cutting process to block an entry of external light.

In an embodiment of the present invention, the scorched surface is composed of carbide.

In an embodiment of the present invention, carbon content of the scorched surface is not less than 5%, and oxygen content of the scorched surface is not less than 5%.

In an embodiment of the present invention, the scorched surface at least covers side positions of the semiconductor structure.

In an embodiment of the present invention, the semiconductor structure is made of III-V group semiconductor materials.

In an embodiment of the present invention, the semiconductor structure is composed of a compound semiconductor of indium phosphide and indium gallium arsenide.

In an embodiment of the present invention, the at least one laser cutting process includes a first laser cutting process, a second laser cutting process and a third laser cutting process, and an output power, a reference frequency and a moving speed of a laser used in the first laser cutting process are 0.2-1 W, 10-18 kHz, 30-70 mm/s, respectively.

In an embodiment of the present invention, an output power, a reference frequency and a moving speed of lasers used in the second laser cutting process and the third laser cutting process are 1-5 W, 8-13 kHz, and 100-180 mm/s, respectively.

The present invention also includes a light sensing element manufactured using the aforementioned manufacturing method. The light sensing element includes a plurality of sidewalls, a semiconductor structure and a bandpass filter layer. Each of the sidewalls forms a scorched surface to block an entry of external light. The semiconductor structure includes a light absorbing layer. The bandpass filter layer is stacked on the semiconductor structure.

In an embodiment of the present invention, the bandpass filter layer is stacked with a combination of 15-20 groups of hydrogen silicide material layers and silicon dioxide material layers.

Accordingly, the present invention uses a laser cutting process to cut the light-sensing element into shape and to form a scorched surface on each sidewall of the light-sensing element to block the external light from the sidewall into the light absorbing layer in the light sensing element so that the light sensing element can reduce the noise generation.

### BRIEF DESCRIPTION OF THE DRAWINGS

FIG. 1 is a flowchart of the manufacturing method of the light sensing element of the present invention.

FIG. 2 is a schematic view of the structures during the manufacturing process in accordance with FIG. 1.

FIG. 3 is a schematic view in structure of an embodiment of the light sensing element of the present invention.

FIG. 4 shows actual spectral characteristics of a conventional light sensing element and the light sensing element of the present invention.

### DETAILED DESCRIPTION OF THE PREFERRED EMBODIMENT

Since the various aspects and embodiments are merely illustrative and not restrictive, after reading this specification, there may also be other aspects and embodiments without departing from the scope of the present invention to a person having ordinary skill in the art. The features and advantages of these embodiments and the scope of the patent application will be better appreciated from the following detailed description.

Herein, “a” or “an” is used to describe one or more devices and components described herein. Such a descriptive term is merely for the convenience of illustration and to provide a general sense of the scope of the present invention. Therefore, unless expressly stated otherwise, the term “a” or “an” is to be understood to include one or at least one, and the singular form also includes the plural form.

Herein, the terms “first” or “second” and similar ordinal numbers are mainly used to distinguish or refer to the same or similar devices or structures, and do not necessarily imply the spatial or temporal order of such devices or structures. It should be understood that in certain situations or configurations, ordinal numbers may be used interchangeably without affecting the practice of the present invention.

As used herein, the term “comprise” “include,” “have” or any other similar term is not intended to exclude additional, unrecited elements. For example, a device or structure comprising/including/having a plurality of elements is not limited to the elements listed herein but may comprise/include/have other elements not explicitly listed but generally inherent to the device or structure.

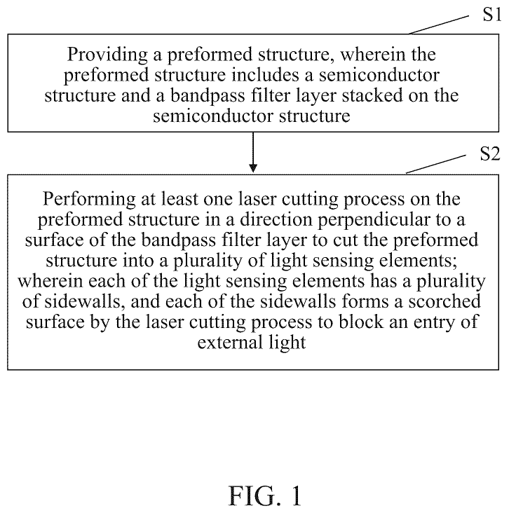

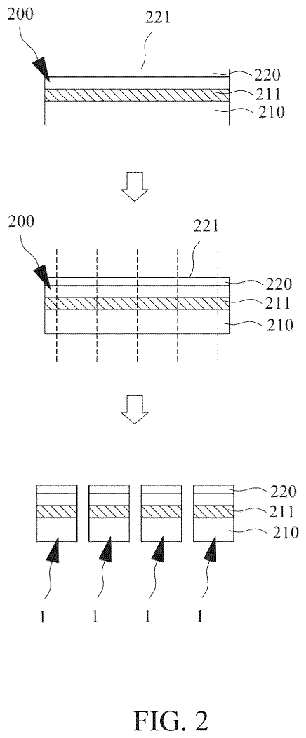

Please refer to FIG. 1 and FIG. 2 together for the following descriptions. FIG. 1 is a flowchart of the manufacturing method of the light sensing element of the present invention, and FIG. 2 is a schematic view of the structures during the process corresponding to FIG. 1. As shown in FIGS. 1 and 2, the manufacturing method of the light sensing element of the present invention includes the following steps:

Step S1: providing a preformed structure, wherein the preformed structure includes a semiconductor structure and a bandpass filter layer stacked on the semiconductor structure.

First, the present invention forms the preformed structure 200 of the light sensing element by a semiconductor process so as to provide the preformed structure 200 for subsequent processing steps. The preformed structure 200 at least includes a semiconductor structure 210 and a bandpass filter layer 220 stacked on the semiconductor structure 210. The semiconductor structure 210 is mainly a multilayer structure composed of semiconductor materials stacked by an epitaxy process. In an embodiment of the present invention, the semiconductor structure 210 is made of III-V group semiconductor materials. The structure of each layer may adopt different combinations of III-V group semiconductor materials, and selectively doping specific elements according to design requirements to form a semiconductor material layer with different characteristics, but the present invention is not limited thereto. The semiconductor structure 210 includes a light absorbing layer 211. The light absorbing layer 211 is used to absorb light entering the structure. In addition, the semiconductor structure 210 may also include a layered structure formed of other materials by corresponding processes, e.g., an electrode layer, an insulating layer, an anti-reflection layer, etc.

The bandpass filter layer 220 is substantially stacked on the semiconductor structure 210. The bandpass filter layer 220 is mainly used to limit the passage of light in a single or multiple specific spectra, and to block the passage of light outside the aforementioned specific spectra (e.g., the so-called stop band spectrum). The bandpass filter layer 220 is a multilayer structure stacked with light-transmitting materials by a coating process. Different material combinations may be used for the structure of each layer so that the bandpass filter layer 220 can be formed with the characteristics for allowing the light in the specific spectra in the different ranges to pass through it and for blocking the light in the different spectra from passing through it according to the design requirements. For example, in an embodiment of the present invention, the bandpass filter layer 220 includes a plurality of layered structures, wherein the plurality of layered structures are stacked with a combination of 15-20 groups of hydrogen silicide material layers and silicon dioxide material layers. In other words, the bandpass filter layer 220 uses a layer composed of a hydrogen silicide material layer and a silicon dioxide material layer as a group, and such layers are gradually stacked into 15-20 groups to form the bandpass filter layer 220, but the number of layers and the material selection of the bandpass filter layer 220 are not limited to the above.

Step S2: performing at least one laser cutting process on the preformed structure in a direction perpendicular to a surface of the bandpass filter layer to cut the preformed structure into a plurality of light sensing elements;

wherein each of the light sensing elements has a plurality of sidewalls, and each of the sidewalls forms a scorched surface by a laser cutting process to block an entry of external light.

After the preformed structure 200 is provided in the above step S1, the present invention can then perform at least one laser cutting process on the preformed structure 200 in the direction perpendicular to the surface 221 of the bandpass filter layer 220 to cut the preformed structure 200 into a plurality of light sensing elements 1. In other words, each light sensing element 1 will include a part of the aforementioned semiconductor structure 210 and a part of the aforementioned bandpass filter layer 220. Each light sensing element 1 formed by cutting has a plurality of sidewalls. For example, the light sensing element 1 from cutting is generally a rectangular body such that the light sensing element 1 has four sidewalls. The size of each light sensing element 1 May be varied according to different design requirements.

Since the laser cutting process uses a high-energy focused laser to perform cutting operations on the preformed structure 200, during forming the plurality of light sensing elements 1 from cutting, the high-energy laser is used to cause material sintering on the sidewalls of the light sensing element 1 to form a scorched surface. The aforementioned scorched surface is a rough surface, and the scorched surface is mainly composed of carbides. That is to say, a carbide layer can be formed on each sidewall of each light sensing element 1, and the carbide layer can absorb the light irradiating the sidewall, thereby providing the effect of blocking the entry of external light.

In an embodiment of the present invention, at least one laser cutting process may include a first laser cutting process, a second laser cutting process, and a third laser cutting process performed in sequence. An output power, a reference frequency and a moving speed of a laser used in the first laser cutting process are 0.2-1 W, 10-18 kHz, 30-70 mm/s, respectively. An output power, a reference frequency and a moving speed of lasers used in the second laser cutting process and the third laser cutting process are 1-5 W, 8-13 kHz, and 100-180 mm/s, respectively. The lasers selected for these laser cutting processes provide sufficient output power and reference frequency to match the moving speed during the cutting process to form a scorched surface on each sidewall of the light sensing element 1 formed from cutting. However, the selected parameters of the lasers and the number of times the laser cutting processes are performed are not limited thereto.

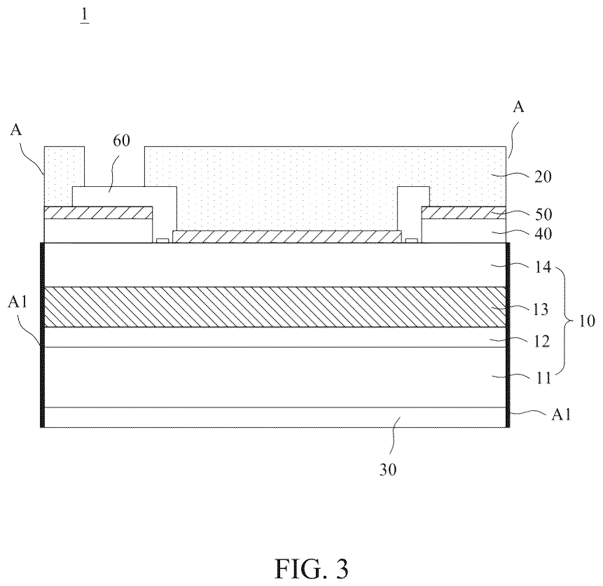

Please refer to FIG. 3 which is a schematic view in structure of an embodiment of the light sensing element of the present invention. The light sensing element of the present invention is manufactured by the manufacturing method of the aforementioned light sensing element. The structure of the light sensing element of the present invention is further described below. As shown in FIG. 3, in this embodiment, the light sensing element 1 of the present invention at least includes a plurality of sidewalls A, a semiconductor structure 10 and a bandpass filter layer 20. The semiconductor structure 10 is the basic structure of the light sensing element 1 of the present invention. The semiconductor structure 10 can be roughly divided into a substrate 11, a first semiconductor layer 12, a light absorbing layer 13 and a second semiconductor layer 14. The substrate 11 is mainly made of indium phosphide (InP) material. The first semiconductor layer 12 is mainly made of silicon-doped indium phosphide (InP) material. The light absorbing layer 13 is mainly made of undoped indium gallium arsenide (InGaAs) material. The second semiconductor layer 14 is mainly made of silicon-doped indium phosphide material. The semiconductor structure 10 May form a first electrode 30 on the other side of the substrate 11, and the first electrode 30 is mainly made of an alloy material containing gold (Au).

A protective layer 40, an anti-reflection layer 50 and a second electrode 60 May be further provided between the semiconductor structure 10 and the bandpass filter layer 20. The protective layer 40 is formed on the other side surface of the second semiconductor layer 14 of the semiconductor structure 10, and the protective layer 40 is mainly made of silicon oxide (SiOx) material. The anti-reflection layer 50 is formed on the protective layer 40 and the other side surface of the second semiconductor layer 14 of the semiconductor structure 10, and the anti-reflection layer 50 is mainly made of silicon nitride (SiN) material. The second electrode 60 maintains ohmic contact with the second semiconductor layer 14 of the semiconductor structure 10, and the second electrode 60 is mainly made of a material containing gold. The bandpass filter layer 20 is formed on the anti-reflection layer 50 and the second electrode 60.

When the light sensing element 1 of the present invention is formed from cutting by the laser cutting process, a plurality of sidewalls A will be formed, and a scorched surface A1 will be formed on each sidewall A by a high-energy focused laser. In this embodiment, the scorched surface A1 at least covers the side positions of the semiconductor structure 10. That is, the scorched surface A1 is formed on the side of the structure made of III-V group semiconductor materials. In an embodiment of the present invention, the carbon content of the aforementioned scorched surface A1 is not less than 5%, and the oxygen content of the scorched surface A1 is not less than 5% so that the scorched surface A1 is sufficient to be in a non-transparent state.

Accordingly, the light irradiated to the light sensing element 1 of the present invention can only enter the light absorbing layer 13 of the semiconductor structure 10 through the bandpass filter layer 20. In this way, the light received by the light absorbing layer 13 is generally within a specific spectrum. The light sensing element 1 of the present invention can effectively reduce the possibility of light of other spectra entering the light absorbing layer 13 from the sidewall A by forming the scorched surface A1 so as to reduce the generation of noise.

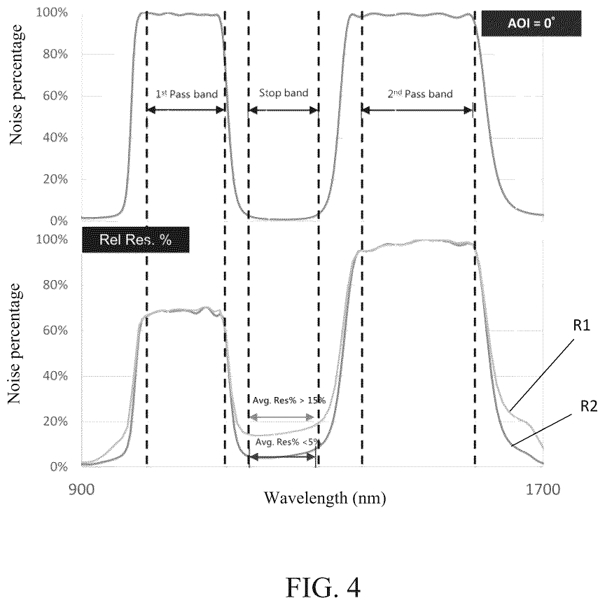

Reference is made to FIG. 4, which shows the test results of the noise percentage of a conventional light sensing element and the noise percentage of the light sensing element of the present invention. In the following experiments, the light sensing element is a light sensor with a bandpass filter as an example. The light sensor formed by a conventional saber saw cutting process is used as a control group R1, and the light sensor formed by the laser cutting process of the present invention is used as the experimental group R2. The noise percentages of both after testing are compared. The upper part of FIG. 4 shows the spectral characteristics corresponding to the bandpass filter. The bandpass filter of the light sensor has a first pass band spectrum with a range of 1000-1150 nm and a second pass band spectrum with a range of is 1350-1600nm, and the corresponding stop band spectrum with a range of 1180-1350 nm. The lower part of FIG. 4 shows the actual spectral characteristics corresponding to the aforementioned control group R1 and experimental group R2. The average noise percentage of the control group R1 was greater than 10% in the aforementioned stop band spectrum interval, while that of the experimental group R2 was less than 5% in the aforementioned stop band spectrum interval. It can be seen that compared with the conventional light sensors made by saber saw cutting, the light sensors made by the manufacturing method of the present invention can obviously provide a lower average noise percentage and can more effectively reduce the generation of noise.

The foregoing detailed description is illustrative in nature only and is not intended to limit the embodiments of the claimed subject matters or the applications or uses of such embodiments. Furthermore, while at least one exemplary embodiment has been presented in the foregoing detailed description, it should be appreciated that a wide variety of modifications to the present invention are possible. It should also be appreciated that the embodiments described herein are not intended to limit the scope, use, or configuration of the claimed subject matters in any way. Instead, the foregoing detailed description is intended to provide a person having ordinary skill in the art with a convenient guide for implementing one or more of the described embodiments. Moreover, various modifications may be made in the function and arrangement of the devices without departing from the scope defined by the claims, including known equivalents and any equivalents that may be anticipated at the time of filing this patent application.

What is claimed is:

1. A manufacturing method of a light sensing element, the method comprising the following steps:
providing a preformed structure, wherein the preformed structure comprises a semiconductor structure and a bandpass filter layer stacked on the semiconductor structure; and
performing at least one laser cutting process on the preformed structure in a direction perpendicular to a surface of the bandpass filter layer to cut the preformed structure into a plurality of light sensing elements;
wherein each of the light sensing elements has a plurality of sidewalls, and each of the sidewalls forms a scorched surface by the at least one laser cutting process to block an entry of external light.

2. The manufacturing method of claim 1, wherein the scorched surface is composed of carbide.

3. The manufacturing method of claim 1, wherein carbon content of the scorched surface is not less than 5%, and oxygen content of the scorched surface is not less than 5%.

4. The manufacturing method of claim 1, wherein the scorched surface at least covers side positions of the semiconductor structure.

5. The manufacturing method of claim 1, wherein the semiconductor structure is made of III-V group semiconductor materials.

6. The manufacturing method of claim 5, wherein the semiconductor structure is composed of a compound semiconductor of indium phosphide and indium gallium arsenide.

7. The manufacturing method of claim 1, wherein the at least one laser cutting process comprises a first laser cutting process, a second laser cutting process and a third laser cutting process, and an output power, a reference frequency and a moving speed of a laser used in the first laser cutting process are 0.2-1 W, 10-18 kHz, 30-70 mm/s, respectively.

8. The manufacturing method of claim 7, wherein an output power, a reference frequency and a moving speed of lasers used in the second laser cutting process and the third laser cutting process are 1-5 W, 8-13 kHz, and 100-180 mm/s, respectively.

9. A light sensing element manufactured by the manufacturing method of claim 1, the light sensing element comprising:
a plurality of sidewalls, each of the sidewalls forming a scorched surface to block an entry of external light;
a semiconductor structure including a light absorbing layer; and
a bandpass filter layer stacked on the semiconductor structure.

10. The light sensing element of claim 9, wherein the bandpass filter layer is stacked with a combination of 15-20 groups of hydrogen silicide material layers and silicon dioxide material layers.
